(19) United States
(12) Patent Application Publication
(10) Pub. No.: US 2018/0006175 A1
(43) Pub. Date: Jan. 4, 2018

(54) SEMICONDUCTOR BULK STRUCTURE AND OPTICAL DEVICE

(71) Applicant: FUJITSU LIMITED, Kawasaki-shi (JP)

(72) Inventor: Mari Ohfuchi, Hadano (JP)

(73) Assignee: FUJITSU LIMITED, Kawasaki-shi (JP)

(21) Appl. No.: 15/618,697

(22) Filed: Jun. 9, 2017

(30) Foreign Application Priority Data
Jun. 30, 2016 (JP) 2016-130352

(51) Int. Cl. H01L 31/0352; H01L 31/032

(52) U.S. Cl. CPC H01L 31/035236; H01L 31/032; H01L 31/0324

(57) ABSTRACT

A semiconductor bulk structure includes a bulk structure including a portion where two layers of GeSe and one layer of WS₂ are alternately laminated.

And an optical device includes a semiconductor bulk structure having a bulk structure including a portion where two layers of GeSe and one layer of WS₂ are alternately laminated.

### CROSS-REFERENCE TO RELATED APPLICATION

This application is based upon and claims the benefit of priority of the prior Japanese Patent Application No. 2016-130352, filed on Jun. 30, 2016, the entire contents of which are incorporated herein by reference.

### FIELD

The embodiments discussed herein are related to a semiconductor bulk structure and an optical device.

### BACKGROUND

Since the discovery of graphene, there have been increasing efforts to enable a material to have a new function by removing one or two layers from a layered substance or laminating the layers.

In the layered substance, each layer is stable, and the interlayer connection is weak. In addition, since the layered substance may be relatively easily synthesized, and each layer thereof may be peeled or laminated, the lamination structure thereof is easily controlled and is distinguishable from a conventional semiconductor superlattice structure that requires a control in an atomic level.

However, a layered substance such as GeSe or WS₂ is a semiconductor having an indirect gap in a bulk.

Meanwhile, when one or two layers are removed from the layered substance in such a bulk, the layered substance becomes a semiconductor having a direct gap.

However, when one or two layers are removed from the layered substance in such a bulk and then the layered substance is placed on a substrate or the like, the nature thereof such as an energy band structure changes.

The followings are reference documents.

### [Document 1] Japanese National Publication of International Patent Application No. 2000-500288 and

### [Document 2] Japanese National Publication of International Patent Application No. 08-504959.

### SUMMARY

According to an aspect of the invention, a semiconductor bulk structure includes a bulk structure including a portion where two layers of GeSe and one layer of WS₂ are alternately laminated.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic perspective view illustrating a configuration of a semiconductor bulk structure according to an embodiment of the present disclosure;

FIG. 2A is a view illustrating an energy band structure of the semiconductor bulk structure according to the embodiment;

FIG. 2B is a view illustrating an energy band structure of two-layer GeSe;

FIG. 2C is a view illustrating an energy band structure of one-layer WS₂;

FIG. 3 is a schematic sectional view illustrating a configuration of an optical device (a solar cell) according to the embodiment; and

FIG. 4 is a schematic sectional view illustrating a configuration of an optical device (a near infrared light emitting/receiving device) according to the embodiment.

### DESCRIPTION OF EMBODIMENTS

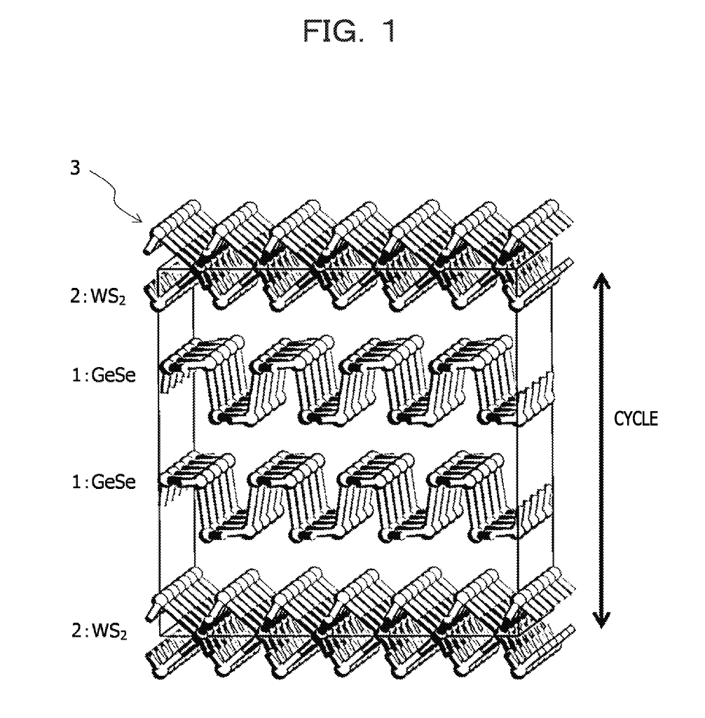

Hereinafter, a semiconductor bulk structure and an optical device according to an embodiment of the present disclosure will be described with reference to FIGS. 1 to 4.

As illustrated in FIG. 1, the semiconductor bulk structure according to the embodiment has a bulk structure including a portion where two layers of GeSe 1 and one layer of WS₂ 2 are alternately laminated. That is, a semiconductor bulk structure 3 is made of a semiconductor bulk material (a semiconductor optical material) in which two layers of GeSe 1 and one layer of WS₂ 2 are alternately laminated. Here, GeSe 1 may also be referred to as a “GeSe layer 1.” In addition, WS₂ 2 may also be referred to as a “WS₂ layer 2.”

Here, the bulk structure has a structure in which two layers of GeSe 1 and one layer WS₂ 2 are alternately laminated over the entire thickness direction thereof. In this case, the lowermost layer may be GeSe or WS₂. The uppermost layer may be GeSe or WS₂.

For example, assuming that a lamination of two layers of GeSe 1 and one layer WS₂ 2 is one cycle, the semiconductor bulk structure 3 may have a bulk structure in which two layers of GeSe 1 and one layer of WS₂ 2 are alternately laminated by 10 or more cycles. In this case, the semiconductor bulk structure 3 has a thickness of about 20 nm or more. Therefore, the semiconductor bulk structure 3 may reliably have a direct gap and be in a stable state where the energy band structure thereof does not change.

Here, while it is described that the bulk structure has a structure in which two layers of GeSe and one layer of WS₂ are alternately laminated over the entire structure in the thickness direction, the bulk structure is not limited thereto.

For example, the bulk structure may include a portion where two layers of GeSe 1 and one layer of WS₂ 2 are alternately laminated, and another layer of GeSe or another layer of WS₂ laminated on the top or bottom side of the portion in the thickness direction.

The bulk structure is configured in this way for the following reasons.

For example, a layered substance such as GeSe or WS₂ is a semiconductor having an indirect gap in a bulk.

Meanwhile, when one or more two layers are removed from the layered substance in a bulk, the layered substance becomes a semiconductor having a direct gap in the bulk.

For example, GeSe is one of layered substances called Group IV monocalcogenides. GeSe is an indirect gap semiconductor in a bulk, and has a small (weak) light absorption/emission intensity. Meanwhile, when one or two layers of GeSe are removed, a direct gap semiconductor having a large quantum efficiency is obtained.

In addition, for example, WS₂ is one of layered substances called transition metal dichalcogenides. WS₂ is an indirect gap semiconductor in a bulk, and when one layer is removed, the WS₂ becomes a direct gap semiconductor.

However, when such a layered substance in a bulk is placed on a substrate in the state where one or two layers are removed therefrom, the nature thereof such as an energy band structure, changes.

For example, when a thin film of GeSe is placed on a substrate, its nature changes. Accordingly, since GeSe is required to be kept floating in the air when making a device using GeSe, it is very difficult to make the device.

Thus, in order to ensure that a layered substance in a bulk has a direct gap and does not suffer from a change of a nature such as an energy band structure even when the layered substance is placed on a substrate, adopted is a semiconductor bulk structure 3 having a bulk structure including a portion where two layers of GeSe 1 and one layer of WS₂ 2 are alternately laminated.

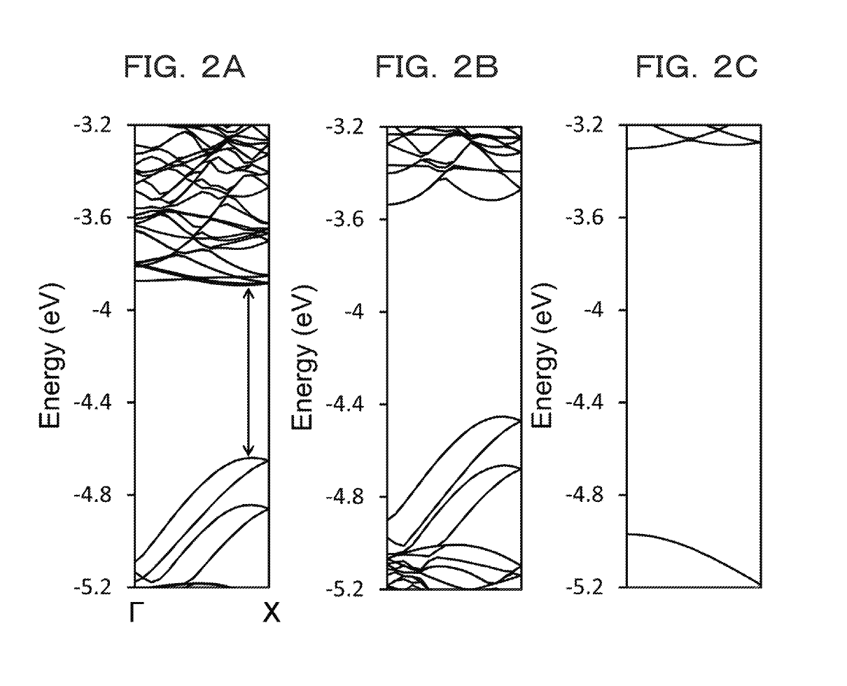

Here, an energy band structure of a semiconductor bulk structure having a bulk structure in which two layers of GeSe and one layer of WS₂ are alternately laminated was calculated (predicted) by using a first principle calculation method (a first principle simulation) that allows a nature of a substance to be predicted with high accuracy without using an empirical parameter. As a result, the result illustrated in FIG. 2A was obtained.

In addition, FIG. 2B illustrates a result obtained by calculating the energy band structure of two layers of GeSe, and FIG. 2C illustrates a result obtained by calculating the energy band structure of one layer of WS₂.

In addition, as illustrated in FIG. 2A, a lattice constant and an atomic arrangement at which the energy becomes the most stable when the atomic arrangement is three-dimensionally relaxed by alternately laminating two layers of GeSe and one layer WS₂, were determined, and the energy band structure was calculated by using the arrangement.

Here, assuming that the lamination of two layers of GeSe 1 and one layer of WS₂ 2 is one cycle, and the semiconductor bulk structure 3 has a bulk structure in which two layers of GeSe 1 and one layer of WS₂ 2 are alternately laminated by 10 cycles.

In view of the energy band structure, it has been found that a direct gap is maintained as illustrated in FIG. 2A (see the arrow in FIG. 2A) even though the semiconductor bulk structure 3 has the bulk structure in which two layers of GeSe 1 and one layer of WS₂ 2 are alternately laminated as described above. That is, it has been found that the direct gap is maintained rather than changing into the indirect gap even if two layers of GeSe 1 and one layer of WS₂ 2 are alternately laminated to form a bulk structure. Meanwhile, the direct gap may also be referred to as a direct band gap.

Thus, with the semiconductor bulk structure 3 having a bulk structure including a portion where two layers of GeSe 1 and one layer of WS₂ 2 are alternately laminated, a bulk structure (a bulk material) having a large direct gap with large quantum efficiency may be obtained, and even when the semiconductor bulk structure 3 is placed on, for example, a substrate, it is possible to prevent a nature such as an energy band structure, from changing. Hence, it is very easy to make a device.

In addition, since the light absorption/emission intensity is proportional to the number of layers, the light absorption/emission intensity may be made large (strong) by using the bulk structure as described above.

In addition, it has also been found that the band gap of the semiconductor bulk structure 3 having a bulk structure in which two layers of GeSe 1 and one layer of WS₂ 2 are alternately laminated is originated from the two layers of GeSe (thin film of GeSe) having a band gap of about 1.4 eV, and the semiconductor bulk structure has a band gap of about 1.4 eV, as illustrated in FIGS. 2A and 2B.

In addition, in the first principle simulation, an absolute value of the band gap becomes smaller than an experimental value. Hence, in FIGS. 2A and 2B, the absolute value of the band gap becomes smaller than about 1.4 eV.

Here, the band gap of about 1.4 eV is a band gap corresponding to a near infrared region. That is, the semiconductor bulk structure 3 of the embodiment has a band gap corresponding to the near infrared region.

Accordingly, the nature of a material suitable for application to a near infrared device including, for example, a solar cell is maintained.

That is, a material having a band gap of about 1.4 eV is considered optimal as, for example, an optical material for a solar cell. In addition, since the near infrared region is hard to be absorbed into the human body, the material is also expected to be used for, for example, a bio-imaging device and demanded to be adopted as a material replacing GaAs or a lead-free material.

Meanwhile, GeSe is a semiconductor having an indirect band gap of about 1.1 eV in a bulk, and becomes a semiconductor having a direct band gap of about 1.4 eV when one or two layers are removed therefrom.

As described above, the semiconductor bulk structure 3 having a bulk structure in which two layers of GeSe 1 and one layer of WS₂ 2 are alternately laminated is also originated from the two-layer GeSe having a band gap of about 1.4 eV, and has a band gap of about 1.4 eV.

Hence, the semiconductor bulk structure 3 having a bulk structure in which two layers of GeSe 1 and one layer of WS₂ 2 are alternately laminated maintains the nature of a material suitable for application to a near infrared device including, for example, a solar cell.

Next, a method of manufacturing a semiconductor bulk structure 3 having a bulk structure in which two layers of GeSe 1 and one layer of WS₂ 2 are alternately laminated as described above will be described with specific examples.

First, a Ge powder and a Se powder in a ratio of 1:1 are processed in a crucible for about 30 minutes.

Subsequently, the obtained powder is transferred into a vessel, and the vessel is placed in a vacuum furnace.

A base pressure of the vacuum furnace is set to about 10 mTorr, about 200 sccm of Ar gas is caused to flow thereinto, and the vacuum furnace is kept at about 480° C. for about 4 hours.

After a natural cooling to the room temperature, the powder is recovered so as to obtain a bulk GeSe material.

This bulk GeSe material is put into a vessel. The vessel is placed at one end of a quartz tube, and a Si substrate is placed at the other end of the quartz tube.

The quartz tube is placed in the vacuum furnace again, about 100 sccm of Ar carrier gas is caused to flow thereinto, and the vessel containing GeSe and the Si substrate are kept at about 640° C. and about 400° C., respectively.

After a natural cooling to the room temperature, the Si substrate is recovered so as to obtain two layers of GeSe.

Next, an S powder, a WO₃ powder, and a sapphire substrate are placed in a vacuum furnace, about 80 sccm of Ar gas is caused to flow thereinto, and the vacuum furnace is kept at about 900° C. for about 60 minutes so as to obtain one layer of WS₂.

The thin films of GeSe and WS₂ obtained in this way are put into deionized water vessels, respectively, for about 30 seconds, and GeSe and WS₂ which are peeled from the substrate are deposited on a PDMS.

By alternately and repeatedly stamping GeSe and WS₂ from the PDMSs on which GeSe and WS₂ are deposited, on another substrate, the semiconductor bulk structure 3 having a bulk structure in which two layers of GeSe 1 and one layer of WS₂ 2 are alternately laminated may be obtained.

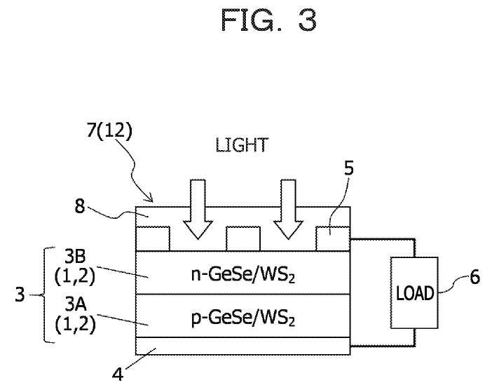

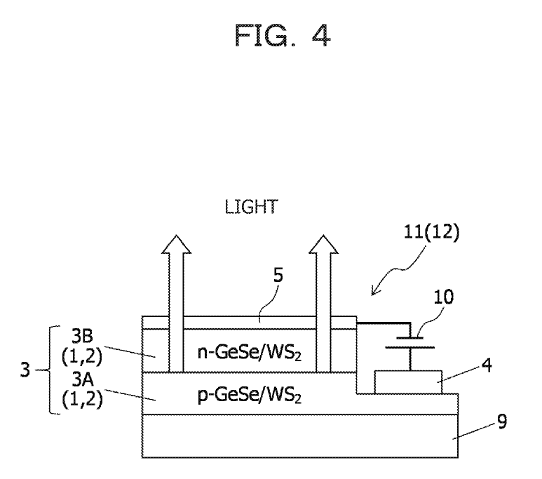

As described above, the semiconductor bulk structure 3 may be used for an optical device 12 (see, e.g., FIGS. 3 and 4).

In this case, the optical device 12 has the above-described semiconductor bulk structure 3 (see, e.g., FIGS. 3 and 4).

For example, the semiconductor bulk structure 3 may be used for the optical device 12 employing a pn junction (a pn lamination structure) such as a solar cell or a near infrared light emitting/receiving device (see, e.g., FIGS. 3 and 4). In addition, the above-described semiconductor bulk structure 3 may also be used for an optical device other than the optical device employing a pn junction.

In this case, the semiconductor bulk structure 3 may be provided with a p-type region 3A and an n-type region 3B. For example, the p-type region 3A may include p-type GeSe, and the n-type region 3B may include n-type GeSe.

For example, as illustrated in FIG. 3, a solar cell 7 may be constructed by providing a p-side electrode 3A and an n-side electrode 5 to the semiconductor bulk structure, which has a bulk structure in which two layers of GeSe 1 and one layer of WS₂ 2 are alternately laminated and includes the p-type region 3A and the n-type region 3B, and connecting a load 6 to the electrodes 4 and 5. Meanwhile, in FIG. 3, reference numeral 8 indicates a protective film.

In addition, as illustrated in FIG. 4, a near infrared light emitting/receiving device 11 may be constructed by providing a semiconductor bulk structure 3, which has a bulk structure in which two layers of GeSe 1 and one layer of WS₂ 2 are alternately laminated on a substrate 9 and includes a p-type region 3A and an n-type region 3B, providing a p-side electrode 4 and an n-side electrode 5 to the semiconductor bulk structure 3, and connecting a power source 10 to the electrodes 4 and 5.

Meanwhile, the semiconductor bulk structure 3 including a p-type region 3A and an n-type region 3B as described above may be manufactured as follows.

First, at the time of processing the powders in the above-described method of manufacturing the semiconductor bulk structure 3, P is mixed with the powders by about 1% so as to obtain p-type GeSe.

In addition, the temperature is set to about 500° C. to introduce a Se defect so that n-type GeSe is obtained.

Each of p-type GeSe and n-type GeSe obtained in this way, and WS₂ are put into deionized water vessels, respectively, for about 30 seconds, and each of p-type GeSe and n-type GeSe, and WS₂ which are peeled from the substrate are deposited on a PDMS.

By first alternately and repeatedly stamping p-type GeSe and WS₂ from the PDMS on which the p-type GeSe and WS₂ are deposited, on another substrate, and then, alternately and repeatedly stamping n-type GeSe and WS₂ from the PDMS on which the n-type GeSe and WS₂ are deposited, a semiconductor bulk structure 3 having a bulk structure in which two layers of GeSe 1 and one layer of WS₂ 2 are alternately laminated, provided with a p-type region 3A including p-type GeSe and a n-type region 3B including n-type GeSe, and having a pn junction may be obtained.

Therefore, the semiconductor bulk structure and the optical device according to the embodiment have the direct gap and achieve the effect on suppressing the nature such as the energy band structure from changing even when the semiconductor bulk structure is placed on a substrate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor bulk structure comprising:
a bulk structure including a portion where two layers of GeSe and one layer of WS₂ are alternately laminated.

2. The semiconductor bulk structure according to claim 1, wherein the bulk structure has a structure in which two layers of GeSe and one layer of WS₂ are alternately laminated over the entire bulk structure in a thickness direction.

3. The semiconductor bulk structure according to claim 1, wherein the bulk structure includes the portion where two layers of GeSe and one layer of WS₂are alternately laminated, and another layer of GeSe or another layer of WS₂ which is laminated on a top or bottom side of the portion in a thickness direction.

4. The semiconductor bulk structure according to claim 1, wherein the semiconductor bulk structure has a band gap corresponding to a near infrared region.

5. An optical device comprising:
a semiconductor bulk structure having a bulk structure including a portion where two layers of GeSe and one layer of WS₂are alternately laminated.

6. The optical device according to claim 5, wherein the bulk structure has a structure in which two layers of GeSe and one layer of WS₂ are alternately laminated over the entire bulk structure in a thickness direction.

7. The optical device according to claim 5, wherein the bulk structure includes the portion where two layers of GeSe and one layer of WS₂are alternately laminated, and another GeSe or another WS₂ laminated on a top or bottom side the portion in a thickness direction.

8. The optical device according to claim 5, wherein the semiconductor bulk structure has a band gap corresponding to a near infrared region.

9. The optical device according to claim 5, wherein the semiconductor bulk structure includes a p type region and an n type region.

10. The optical device according to claim 9, wherein the p type region includes p type GeSe, and the n type region includes n type GeSe.
